(19) United States
(12) Patent Application Publication
(10) Pub. No.: US 2017/0062250 A1
(43) Pub. Date: Mar. 2, 2017

(54) VACUUM PROCESS APPARATUS AND METHOD OF MANUFACTURING SEMICONDUCTOR DEVICE

(71) Applicant: Renesas Electronics Corporation, Tokyo (JP)

(72) Inventors: Katsuyoshi KOGURE, Ibaraki (JP); Kotaro HORIKOSHI, Ibaraki (JP); Kaichiro KOBAYASHI, Ibaraki (JP); Kazuyuki OZEKI, Ibaraki (JP)

(21) Appl. No.: 15/220,443

(22) Filed: Jul. 27, 2016

(30) Foreign Application Priority Data
Aug. 24, 2015 (JP) 2015-164928

(51) Int. Cl. H01L 21/67; H01L 21/324; H01L 21/66

(52) U.S. Cl. CPC H01L 21/67201; H01L 22/20; H01L 21/67115; H01L 21/324

(57) ABSTRACT

An asking apparatus includes a load-lock chamber and an apparatus control unit. The load-lock chamber takes in or out a semiconductor wafer to or from a process chamber in which a vacuum process of the semiconductor wafer is performed. The apparatus control unit controls a venting process for putting the load-lock chamber in a vacuum state to an atmospheric state in which the load-lock chamber is opened to atmosphere. Also, the apparatus control unit compares −1 kPa that is a pressure value previously set and a differential pressure value obtained by subtracting a second pressure value that is a pressure inside the load-lock chamber right after venting to the atmosphere from a first pressure value that is a pressure inside the load-lock chamber right before venting. The apparatus control unit outputs an alarm when the differential pressure value is lower than −1 kPa that is a pressure value previously set.

### CROSS-REFERENCE TO RELATED APPLICATION

The present application claims priority from Japanese Patent Application No. 2015-164928 filed on Aug. 24, 2015, the content of which is hereby incorporated by reference into this application.

### TECHNICAL FIELD OF THE INVENTION

The present invention relates to a vacuum process apparatus and a method of manufacturing a semiconductor device. The present invention particularly relates to a technique effectively applied to time management of an after-purge after a vacuum process.

### BACKGROUND OF THE INVENTION

In an ashing apparatus that is one of vacuum process apparatuses, after an ashing process of a semiconductor wafer is finished, the semiconductor wafer is transferred to a load-lock chamber. Then, the semiconductor wafer is transferred to a front-end module from the load-lock chamber.

Upon passing the semiconductor wafer from the load-lock chamber to the front-end module, the load-lock chamber is opened to the atmosphere. Upon opening to the atmosphere, the load-lock chamber is first purged by, for example, nitrogen (N₂) gas, which is called “main purge.”

Then, when the pressure in the load-lock chamber reaches a pre-set pressure or higher, an after-purge is performed. After the after-purge is finished, an atmosphere gate valve is vented (opened) to make the load-lock chamber opened to the atmosphere.

### SUMMARY OF THE INVENTION

In the technique of venting to the atmosphere in a load-lock chamber described above, when the after-purge is finished, the atmosphere gate valve is opened, so that the load-lock chamber is opened (vented) to the atmosphere. Thus, if the pressure in the load-lock chamber is not increased even after the after-purge for some reason, a large pressure difference is generated between the load-lock chamber and the front-end module.

In such a situation, when the atmosphere gate valve is opened, the pressure difference causes the atmospheric air to flow into the load-lock chamber from the front-end module, and it poses a problem of jumping of an asked semiconductor wafer due to the pressure of the flowed atmospheric air.

Due to the jumping of the semiconductor wafer, the semiconductor wafer may come into contact with a place rack for storing a plurality of semiconductor wafers, and as a result, it may cause breakage of the semiconductor wafer(s).

The above and other preferred aims and novel characteristics of the present invention will be apparent from the description of the present specification and the accompanying drawings.

The typical ones of the inventions disclosed in the present application will be briefly described as follows.

That is, a typical vacuum process apparatus includes a load-lock chamber and a control unit. The load-lock chamber takes in and out a semiconductor wafer to and from a process chamber in which a vacuum process of the semiconductor wafer is performed. The control unit controls a venting process for putting the load-lock chamber in a vacuum state to an atmospheric state in which the load-lock chamber is opened to atmosphere.

The control unit compares a first set pressure value and a differential pressure value that is obtained by subtracting a second pressure value that is a pressure inside the load-lock chamber right after venting to the atmosphere from a first pressure value that is a pressure inside the load-lock chamber right before venting to the atmosphere, and outputs an alarm when the differential pressure value is lower than the first set pressure value.

Particularly, the control unit compares the differential pressure value and a second set pressure value when the differential pressure value is higher than the first set pressure value, and increases a purge time taken for a purge performed before venting to the atmosphere in the load-lock chamber when the differential pressure value is within a range of the second set pressure value.

The effects obtained by typical ones of the inventions disclosed in the present application will be briefly described below.

Failures in manufacturing of semiconductor devices can be reduced.

### BRIEF DESCRIPTIONS OF THE DRAWINGS

FIG. 1 is an explanatory diagram illustrating an example of a configuration of an ashing apparatus according to an embodiment;

FIG. 2 is an explanatory diagram illustrating an example of a connection configuration of a load-lock chamber and an atmospheric transporting chamber in the ashing apparatus of FIG. 1;

FIG. 3 is an explanatory diagram illustrating an example of a configuration of an apparatus control unit in the ashing apparatus of FIG. 1;

FIG. 4 is a flow chart illustrating an example of a venting process by the ashing apparatus of FIG. 1;

FIG. 5 is an explanatory diagram illustrating an example of a manufacturing process of a semiconductor device in which the ashing apparatus of FIG. 1 is used;

FIG. 6A is an explanatory diagram illustrating an example of a transition of pressure inside the load-lock chamber during the venting process which the inventors of the present invention have studied; and

FIG. 6B is an explanatory diagram illustrating another example of a transition of pressure inside the load-lock chamber during the venting process which the inventors of the present invention have studied.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Furthermore, in the embodiments described below, it goes without saying that the components (including element steps) are not always indispensable unless otherwise stated or except the case where the components are apparently indispensable in principle.

Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Also, the same components are denoted by the same reference symbols throughout the drawings for describing the embodiments, and a repetitive description thereof is omitted.

<Configuration Example of Ashing Apparatus>

Hereinafter, an embodiment will be described in detail.

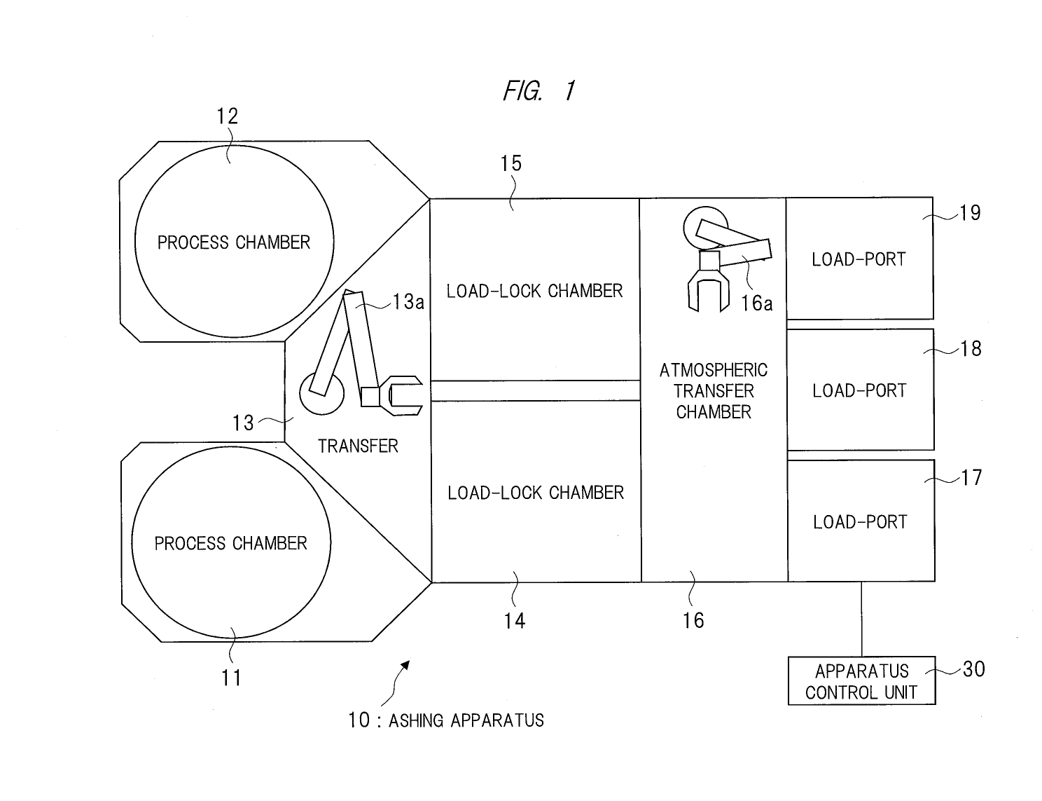

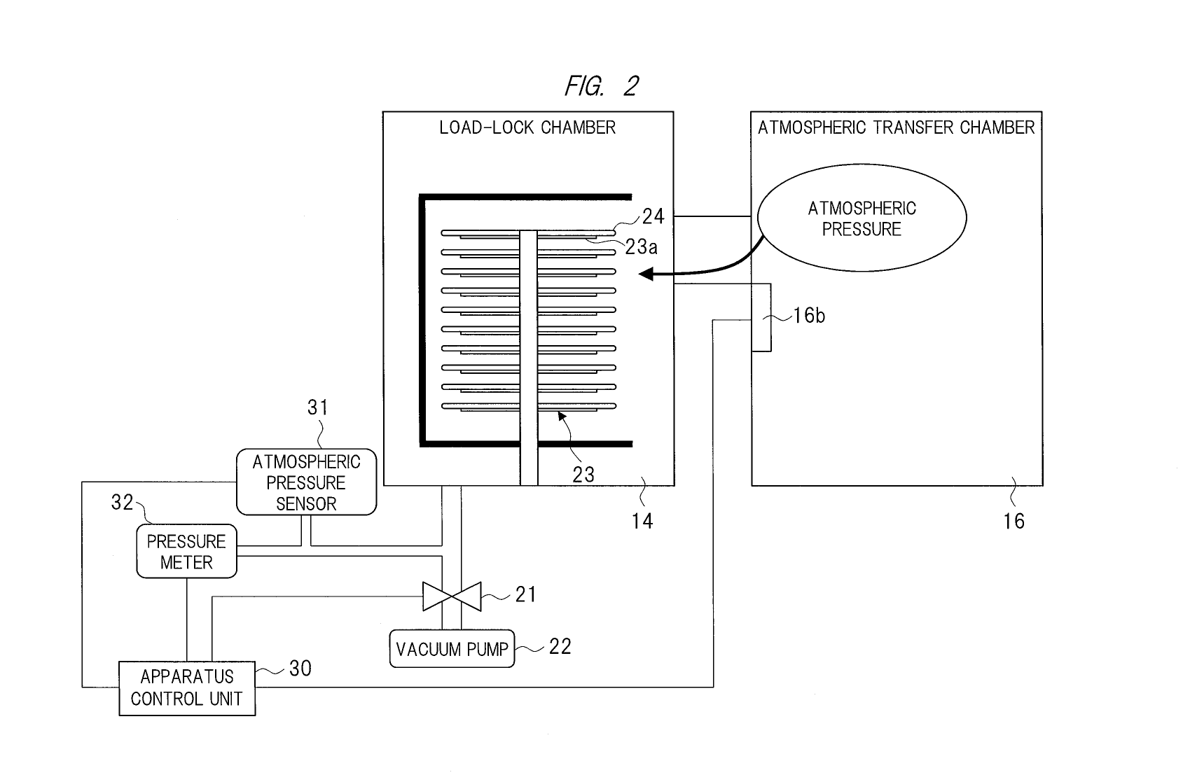

FIG. 1 is an explanatory diagram illustrating an example of a configuration of an ashing apparatus according to the embodiment. FIG. 2 is an explanatory diagram illustrating an example of a connection configuration of a load-lock chamber 14 and an atmospheric transfer chamber 16 in the ashing apparatus 10 of FIG. 1.

The ashing apparatus 10 which is a vacuum process apparatus includes process chambers 11 and 12, a transfer 13, load-lock chambers 14 and 15, the atmospheric transfer chamber 16, load-ports 17 to 19, and an apparatus control unit 30, as illustrated in FIG. 1.

The process chambers 11 and 12 which are chambers for processing are vacuum process chambers for, for example, removing a photoresist formed on a semiconductor wafer, that is, an ashing process. The process chambers 11 and 12 are, for example, plasma ashing apparatuses.

At the stage before the process chambers, the transfer 13 is provided. The transfer 13 is a vacuum transfer chamber. A transfer robot 13a is provided inside the transfer 13.

The transfer robot 13a performs transfer of semiconductor wafers between the process chambers 11 and 12 and the load-lock chambers 14 and 15 provided at the previous stage of the transfer 13.

The load-lock chambers 14 and 15 are vacuum chambers for taking in and out semiconductor wafers without allowing the process chambers 11 and 12 to be vented to the atmosphere. At the previous stage of the load-lock chambers 14 and 15, the atmospheric transfer chamber 16 is provided. The atmospheric transfer chamber 16 is also called an enclosure which forms a closed space isolating semiconductor wafers from contaminating sources to make clean environment.

The atmospheric transfer chamber 16 includes a transfer robot 16a. The transfer robot 16a carries semiconductor wafers in the load-lock chambers 14 and 15 and also takes out semiconductor wafers from the load-lock chambers 14 and 15.

At the previous stage of the atmospheric chamber 16, the load-ports 17 to 19 are provided. The load-ports 17 to 19 are interface units for supplying semiconductor wafers to the process chambers 11 and 12.

The load-ports 17 to 19 take the role of loading semiconductor wafers before being subjected to the ashing process, and storing semiconductor wafer after being subjected to the ashing process in a carrier to pass semiconductor wafers to a transfer system.

The apparatus control unit 30 which is a control unit controls operations of the ashing apparatus 10 and also controls a venting process in the load-lock chambers 14 and 15 to be described later. Particularly, in the venting process, the apparatus control unit 30 manages after-purge time.

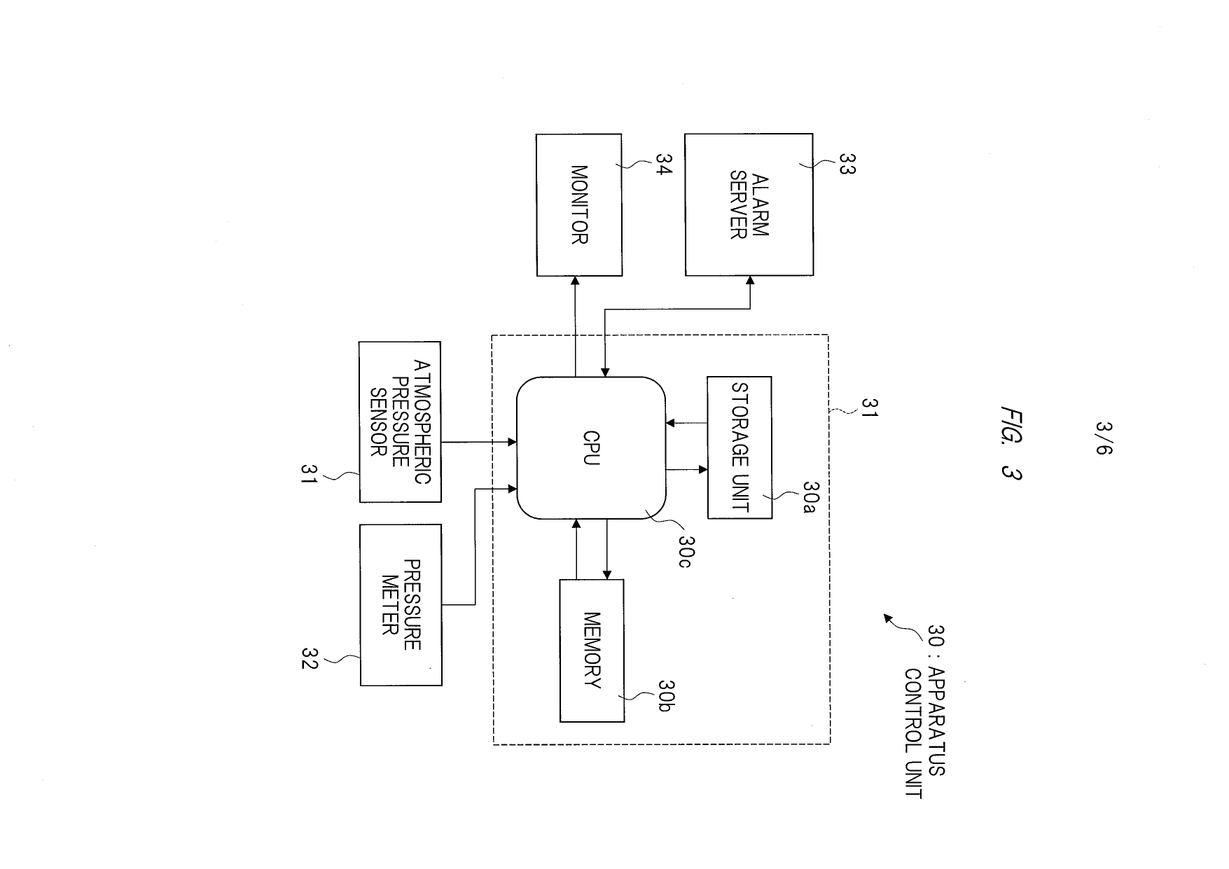

A vacuum pump 22 is connected to the load-lock chamber 14 via a valve 21 as illustrated in FIG. 2. In addition, an atmospheric pressure sensor 31 and a pressure meter 32 included in the apparatus control unit 30 illustrated in FIG. 3 are provided in the load-lock chamber 14.

The atmospheric pressure sensor 31 outputs an atmospheric pressure signal when the pressure inside the load-lock chamber 14 becomes substantially the same as that of the atmospheric pressure. The pressure meter 32 measures the pressure inside the load-lock chamber 14. The atmospheric pressure signal of the atmospheric pressure sensor 31 and a measured value of the pressure measured by the pressure meter 32 are outputted to the apparatus control unit 30.

The vacuum pump 22 draws the vacuum inside the load-lock chamber 14 in combination with the valve 21. Operations of the valve 21 are controlled by the apparatus control unit 30. When the vacuum inside the load-lock chamber 14 is drawn, the valve 21 is set to be in an open state by the apparatus control unit 30. In addition, when venting the inside of the load-lock chamber 14, the valve 21 is set to be in a closed state by the apparatus control unit 30.

In the atmospheric transfer chamber 16, an atmosphere gate valve 16b to be opened upon venting the load-lock chamber 14 is provided. Opening and closing operations of the atmosphere gate valve 16b are controlled by the apparatus control unit 30. Note that, while the load-lock chamber 14 and the atmospheric transfer chamber 16 are illustrated in FIG. 2, the same configuration goes also for the load-lock chamber 15.

<Configuration Example of Apparatus Control Unit>

FIG. 3 is an explanatory diagram illustrating an example of a configuration of the apparatus control unit 30 in the asking apparatus 10 of FIG. 1.

The apparatus control unit 30 includes, as illustrated in FIG. 3, a storage unit 30a, a memory 30b, a CPU (central processing unit) 30c, an alarm server 33, and a monitor 34. The storage unit 30a is formed of a non-volatile memory such as a ROM (read only memory), and program and the like in the form of software to execute processing function in the venting process to be described later are stored therein.

Note that part or all of the respective processing functions in the venting process described above may be achieved by hardware. Alternatively, hardware and software may be used in combination.

The memory 30b is a memory exemplified by a flash memory used as a working area of the CPU 30c. The CPU 30c is, for example, a central processing unit. The CPU 30c monitors the atmospheric pressure signal of the atmospheric pressure sensor 31 and a measurement result of the inside of the load-lock chamber 14 by the pressure meter 32 and executes the venting process in the load-lock chamber 14 based on the program stored in the storage unit 30a.

The alarm server 33 activates an alarm based on an alarm signal outputted from the CPU 30c. The monitor 34 displays an alarm based on the alarm signal outputted from the CPU 30c.

<Process Example of Venting Process>

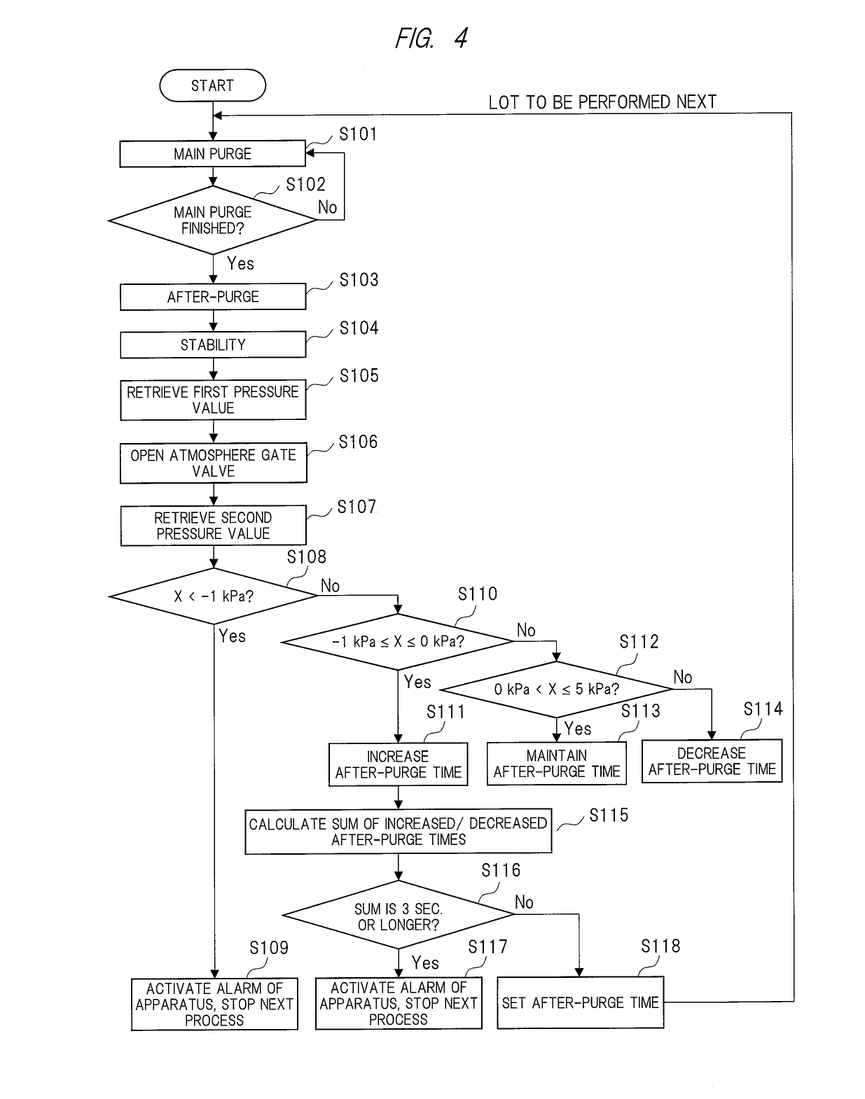

Next, a processing function of the venting process by the apparatus control unit 30 will be described with reference to the flowchart of FIG. 4.

FIG. 4 is a flow chart illustrating an example of a venting process by the ashing apparatus 10 of FIG. 1.

The venting process is a process of putting the load-lock chamber 14 or the load-lock chamber 15 in an atmospheric state in which the load-lock chamber is opened to the atmosphere from a vacuum state upon taking out a semiconductor wafer after being subjected to the ashing process from the load-lock chamber 14 or 15 by the transfer robot 16a of the atmospheric transfer chamber 16 illustrated in FIG. 1. Note that, in FIG. 4, a process example of the venting process in the load-lock chamber 14 is described, by way of example.

First, a main purge is started (step S101). In this main purge, the load-lock chamber 14 in a vacuum state is purged by, for example, nitrogen gas or the like. Next, the CPU 30c determines whether or not the main purge is finished (step S102). This determination that the main purge is finished is a process for determining whether or not the main purge of the process of S101 is finished.

In the process of the step S102, it is determined whether or not the pressure inside the load-lock chamber 14 matches a condition previously set by the main purge. When the pressure matches the previously set condition, it is determined that the main purge is finished.

More specifically, the CPU 30c monitors the atmospheric pressure signal outputted from the atmospheric pressure sensor 31 and a measurement result of the pressure meter 32. Then, when an atmospheric pressure signal is outputted or when the measurement result of the pressure meter 32 shows a pressure value equal to or higher than a pressure value that is previously set, the main purge is determined to be finished. Here, the pressure value that is previously set is a pressure value inside the load-lock chamber 14, for example, about 730 Torr.

In the process of step S102, when it is determined that the main purge is finished, the CPU 30c executes an after-purge (step S103). In this after-purge, purging by nitrogen gas is performed for, e.g., about seven seconds after the determination of the finish of main purge.

Here, a time of seven seconds that is the after-purge time in the process of step S103 is set as a standard after-purge time. Note that the flow rate of the nitrogen gas in the after-purge is same as that of the nitrogen gas in the main purge.

When the after-purge is finished, the process goes to a stability process as a stand-by state for a certain time period (step S104). Here, the stability that is a process of the step S104 is a process performed to stabilize the inside of the load-lock chamber 14. In the stability, the stand-by state is kept for, e.g., about five seconds after the finish of the after-purge.

When the stability is finished, the CPU 30c retrieves a pressure value inside the load-lock chamber 14 from the pressure meter 32 (step S105). The pressure value retrieved in the process of the step S105 is stored in, for example, the memory 30b illustrated in FIG. 3 as a first pressure value.

Then, the CPU 30c opens the atmosphere gate valve 16b in FIG. 2 (step S106) to vent the load-lock chamber 14. Then, the CPU 30c again retrieves a pressure value inside the load-lock chamber 14 from the pressure meter 32 (step S107). The pressure value retrieved in the process of the step S107 is stored in, for example, the memory 30b illustrated in FIG. 3 as a second pressure value.

Next, the CPU 30c accesses the memory 30b to read the first pressure value and the second pressure value and obtains a differential pressure value by subtracting the second pressure value from the first pressure value. From a result, whether or not the differential pressure value is lower than −1 kPa (Pascal) that is a set pressure value previously set is determined (step S108). This value of −1 kPa is a first set pressure value.

In the process of the step S108, when the differential pressure value is lower than −1 kPa, the venting is performed in a state in which the pressure inside the load-lock chamber 14 is low. In this situation, it is determined that there is a possibility that jumping of a semiconductor wafer or the like has occurred, and then, an alarm signal is outputted and the ashing process of a semiconductor wafer to be performed next is stopped (step S109).

The alarm server 33 in FIG. 3 which has received the alarm signal outputted in the process of step S109 activates an alarm. The monitor 34 in FIG. 3 which has received the alarm signal displays a message and the like to indicate that there is a possibility that jumping of the semiconductor wafer or the like has occurred and also the ashing process of a semiconductor wafer to be performed next has been stopped.

In addition, in the process of the step S108, as a result of subtraction, it is determined whether or not the differential pressure value is a pressure value between −1 kPa or more and 0 kPa or less which is the set pressure value previously set (step S110). The value range, between −1 kPa or more and 0 kPa or less, is a second set pressure value.

In the process of the step S110, when the differential pressure value is a pressure value between −1 kPa or more and 0 kPa or less, the CPU 30c determines that the pressure inside the load-lock chamber is not high enough after the after-purge although the possibility of the occurrence of jumping of a semiconductor wafer is low, and thus the CPU 30c increases the after-purge time in the lot to be performed next by a preset time (step S111). The time to be increased is, e.g., about one second.

Therefore, the after-purge time in the lot to be performed next is about eight seconds as one second is added to the standard after-purge time. The time of “+1 second” increased in the process of the step S111 is stored in the memory 30b.

In addition, in the process of the step S110, when the differential pressure value is not a pressure value between −1 kPa or more and 0 kPa or less, the CPU 30c determines whether or not the differential pressure value is within a range of larger than 0 kPa to equal to or lower than 5 kPa which is the set pressure value (step S112). The value within a range of larger than 0 kPa to equal to or lower than 5 kPa is previously set.

When the differential pressure value is within a range of larger than 0 kPa to equal to or lower than 5 kPa, the pressure inside the load-lock chamber 14 is determined to be normal and the time of the after-purge in the lot to be performed next is not increased nor decreased and set to be the standard after-purge time, i.e., about seven seconds (step S113).

In addition, in the process of the step S112, when the differential pressure value is larger than 5 kPa, the CPU 30c determines that the pressure inside the load-lock chamber 14 is not normal and decreases the after-purge time in the lot to be performed next by a preset time (step S114). The time to be decreased is, e.g., about one second. Here, the value of 5 kPa is a third set pressure value.

Therefore, the after-purge time in the lot to be performed next is about six seconds obtained by subtracting one second from the standard after-purge time. The time of “−1 second” decreased in the process of the step S114 is stored in the memory 30b.

Then, when any of the processes of the steps S111, S113, or S114 is finished, the CPU 30c obtains a sum of the increased and decreased after-purge times stored in the memory 30b in the processes of the steps S111, S113, or S114 (step S115). Next, the CPU 30c determines whether or not the sum of the after-purge times obtained is three seconds or longer (step S116).

When the sum of the after-purge times is three seconds or longer, the CPU 30c outputs an overtime alarm signal indicating that the sum is three seconds or longer and then stops the ashing process of a semiconductor wafer to be performed next (step S117). In addition, the alarm server 33 receives the overtime alarm signal and then activates an alarm.

When the monitor 34 receives the overtime alarm signal, the monitor 34 displays a message indicating that maintenance of the ashing apparatus 10 is recommended and a message indicating that the ashing process of a semiconductor wafer to be performed next has been stopped, for example.

Note that, in the process of the step S117, the ashing process of a semiconductor wafer to be performed next may not be stopped and only the display of message(s) and activation of an alarm may be performed.

When the sum of after-purge times is three seconds or longer, there is a possibility that any trouble in the vacuum system of the ashing apparatus has occurred. More specifically, a sealing failure of the valve 21 in FIG. 2 and the like may occur.

In the venting process, although the valve 21 is closed, the vacuum pump 22 in FIG. 2 is being operated continuously. Thus, when any sealing failure or the like occurs in the valve 21, the vacuum is drawn even during the main purge and after-purge, and as a result, such a trouble that the pressure inside the load-lock chamber is not sufficiently increased and the like may occur.

Accordingly, recommendation of maintenance of the ashing apparatus 10 is displayed. In this manner, the possibility of early detection of trouble with the ashing apparatus 10 can be increased.

In the process of the step S116 in FIG. 4, when the sum of the after-purge times is shorter than three seconds, the CPU 30c sets an after-purge time to which a time set in any of the steps S111, S113, and S114 is added (step S118).

In this manner, in the process of the step S103 in the lot to be performed next, the after-purge is performed for an after-purge time to which a time set in any of the steps S111, S113, and S114 is added.

Note that the numerical values determined in the respective processes of the steps S108, S110, and S112 in FIG. 4 are only examples and they are not limited to these. For example, there may be an ashing apparatus in which jumping of a semiconductor wafer occurs when the differential pressure value obtained as a result of subtracting the second pressure value from the first pressure value is equal to or lower than −1.5 kPa.

In the case of such an ashing apparatus, regarding the determination in the process of the step S108, it may be designed such that whether or not the differential pressure value is equal to or lower than −1.5 kPa is determined.

In the same manner, as to the time of “1 second” to be increased or decreased to or from the standard after-purge time, it is not particularly limited but may be optional. For example, the increasing/decreasing time may be 0.5 second or 1.5 seconds.

Alternatively, when increasing time from the standard after-purge time, the time to be increased may be longer than the time to be decreased from the standard after-purge time. Alternatively, in the opposite way, when decreasing time from the standard after-purge time, the time to be decreased may be longer than the time to be increased from the standard after-purge time.

<Example of Manufacturing Process>

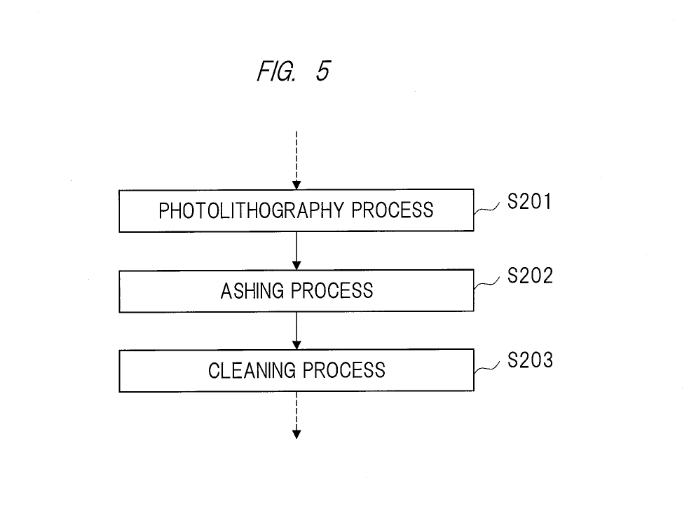

FIG. 5 is an explanatory diagram illustrating an example of a manufacturing process of a semiconductor device in which the ashing apparatus 10 of FIG. 1 is used.

The ashing apparatus 10 of FIG. 1 is used in an ashing process (step S202) after finishing a photolithography process (step S201), as illustrated in FIG. 5. In the photolithography process, a resist pattern is formed by forming an insulating film such as a silicon oxide film formed on a semiconductor wafer and forming a metal film or the like to be a wire, then applying a resist on surfaces of the films, then irradiating light partially onto the resist film using a mask of a predetermined pattern, and then melting unnecessary part of the resist film to be removed through use of a developer. Then, an etching is performed on the resist pattern to form contact holes, wiring patterns, and the like.

Thereafter, by using the ashing apparatus 10 in FIG. 1, unnecessary part of the resist is removed. That is, ashing by irradiating oxygen plasma onto the resist pattern is performed. When the ashing process is finished, the semiconductor wafer is subjected to wet cleaning by a chemical through use of, for example, hydrofluoric acid, ammonia water, or the like, in a cleaning process (step S203).

In such an ashing process, by using the ashing apparatus 10 of the present embodiment, failures such as breakage of semiconductor wafers can be suppressed. In this manner, manufacturing failures of a semiconductor device can be reduced.

<Comparative Example of Pressure Transition Inside Load-Lock Chamber>

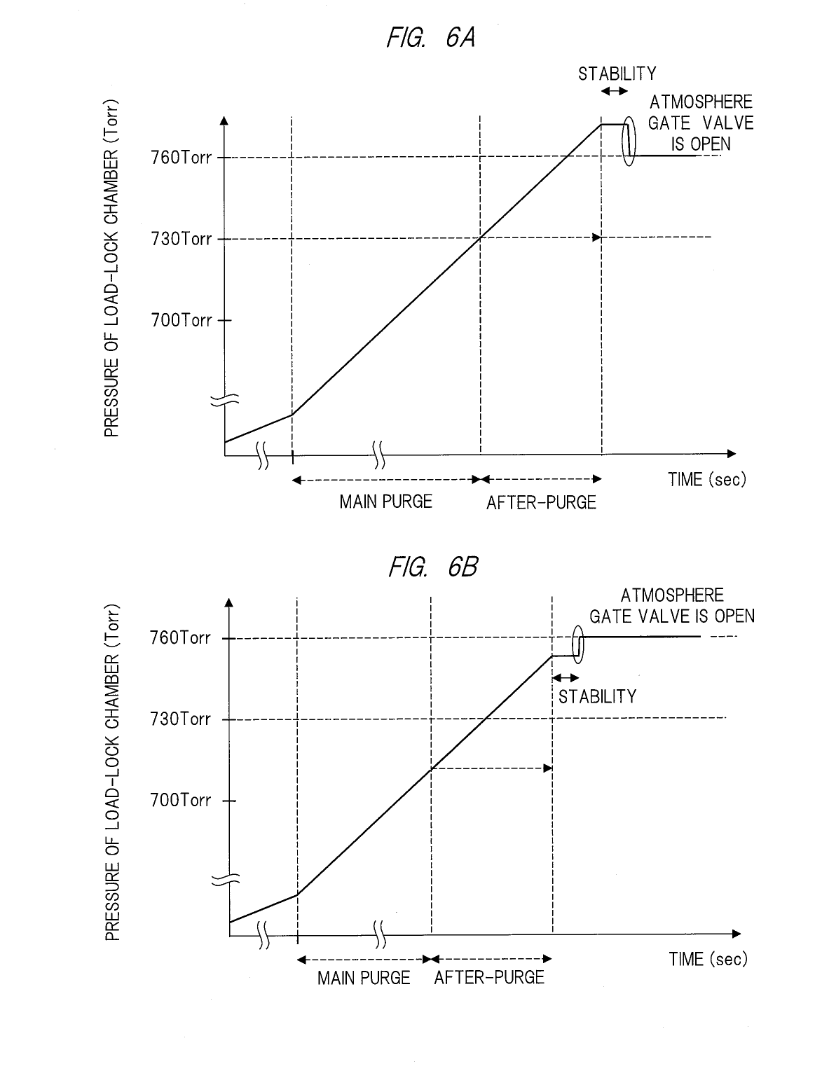

FIGS. 6A and 6B are explanatory diagrams illustrating examples of transitions of pressure inside the load-lock chamber during the venting process which the inventors of the present invention have studied.

FIG. 6A illustrates a pressure transition inside the load-lock chamber in the case where the venting process is normally finished. FIG. 6B illustrates a pressure transition inside the load-lock chamber in the case where the pressure inside the load-lock chamber is kept at a negative pressure. This corresponds to the case where the differential pressure value is determined to be lower than −1 kPa in the process of the step S108 in FIG. 4. Here, in both cases of FIGS. 6A and 6B, the after-purge time is about seven seconds that is the standard after-purge time.

In FIG. 6A, the pressure inside the load-lock chamber is higher than 760 Torr at the timing of finishing the after-purge corresponding to the process of the step S103 in FIG. 4 from the start of the main purge corresponding to the process of the step S101 in FIG. 4.

Subsequently, also in the stability corresponding to the process of the step S104 in FIG. 4, a value higher than 760 Torr is maintained. Thereafter, the pressure inside the load-lock chamber is about 760 Torr by opening of the atmosphere gate valve corresponding to the process of the step S106 in FIG. 4.

In contrast, in the case illustrated in FIG. 6B, at the timing of finishing the after-purge, the pressure inside the load-lock chamber is lower than 760 Torr. This is caused by a calibration failure of the atmospheric pressure sensor, the pressure meter, or the like.

For example, in a case in which calibration of the pressure meter is insufficient, the pressure meter is out of order, or the like, as illustrated in FIG. 6B, even when the pressure inside the load-lock chamber is lower than 730 Torr, a measurement indicating that the pressure inside the load-lock chamber is 730 Torr or higher may be carried out due to an erroneous detection.

In the same manner, also as to the atmospheric pressure sensor, in the case of calibration failure, malfunction, or the like, even when the pressure value is lower than 730 Torr, the atmospheric pressure signal may be outputted due to an erroneous detection.

In this manner, when the main purge is finished in a state where the pressure inside the load-lock chamber is 730 Torr or lower, the pressure inside the load-lock chamber is not increased also in the after-purge, so that the pressure inside the load-lock chamber becomes lower than 760 Torr even after the stability is finished.

That means that the atmosphere gate valve 16b is opened in a state where the pressure inside the load-lock chamber is negative and it makes the pressure inside the load-lock chamber jump up to about 760 Torr.

As illustrated in FIG. 2, a plurality of semiconductor wafers 24 are placed on a place rack 23 for storing the semiconductor wafers 24. As described above, when the atmosphere gate valve 16b is opened, the atmospheric air flows into the load-lock chamber in which the pressure is negative, so that the semiconductor wafers 24 jump due to wind pressure of the flowed atmospheric air.

The semiconductor wafers 24 jumped by the wind pressure come into contact with a rack 23a included in the place rack 23 above the semiconductor wafers, thereby causing breakage or the like of the semiconductor wafers 24.

Conversely, in the case of the ashing apparatus 10 in FIG. 1, when the atmosphere gate valve 16b is opened in a state where the pressure inside the load-lock chamber 14 is negative and accordingly there is a possibility that jumping of semiconductor wafers may occur, the ashing process of a semiconductor wafer to be performed next is stopped, and activation of an alarm, display of a message, or the like is performed like the process of the step S109 in FIG. 4.

In this manner, breakage of a semiconductor wafer to be performed next can be prevented. In addition, transferring a semiconductor wafer that may be broken to the next process can be prevented.

Further, when there is no possibility of jumping of a semiconductor wafer but the pressure inside the load-lock chamber cannot be sufficiently increased in the standard after-purge time, that is, in the case of the process of the step S111 in FIG. 4, the after-purge time is set to be longer than the standard after-purge time. In this manner, it is possible to prevent the pressure inside the load-lock chamber 14 from being negative after finishing the after-purge.

In addition, when increasing of the standard after-purge time is performed repeatedly, there is a possibility that sealing failure of the valve 21 in FIG. 2 may occur as described above. Accordingly, like the process of the step S117 in FIG. 4, the ashing process of a semiconductor wafer to be performed next is stopped, an alarm is activated, and a message indicating recommendation of maintenance of the ashing apparatus 10 and the stop of the ashing process of a semiconductor wafer to be performed next, or the like is displayed.

In this manner, manufacturing failures of a semiconductor device caused by trouble with the ashing apparatus 10 can be reduced.

As described above, damages and the like of semiconductor wafers in the ashing process of the ashing apparatus 10 can be prevented. Accordingly, reliability of a semiconductor device can be improved.

In the foregoing, the invention made by the inventors of the present invention has been concretely described based on the embodiments. However, it is needless to say that the present invention is not limited to the foregoing embodiments and various modifications and alterations can be made within the scope of the present invention.

While the asking apparatus has been described in the embodiment, the embodiment is not limited to this. For example, the embodiment can be used in general apparatuses for vacuum processes like a vacuum vapor-deposition apparatus, a sputtering apparatus, or the like.

The present invention includes various modifications and is not limited to the embodiments. For example, the embodiments are described in detail to simplify the explanation of the present invention. Thus, it is not always necessary to provide all the described configurations.

Moreover, the configurations of one of the embodiments may be partially replaced with those of the other embodiment or the configurations of one of the embodiments may further include the configurations of the other embodiment. Alternatively, the configurations of the embodiments may partially allow the addition of other configurations, deletion, and replacement.

What is claimed is:

1. A vacuum process apparatus comprising:
a load-lock chamber for taking in or taking out a semiconductor wafer to or from a process chamber in which a vacuum process of the semiconductor wafer is performed; and
a control unit for controlling a venting process for putting the load-lock chamber in a vacuum state to an atmospheric state in which the load-lock chamber is opened to atmosphere,
wherein the control unit compares a first set pressure value and a differential pressure value that is obtained by subtracting a second pressure value that is a pressure inside the load-lock chamber right after venting to the atmosphere from a first pressure value that is a pressure inside the load-lock chamber right before venting to the atmosphere, and outputs an alarm when the differential pressure value is lower than the first set pressure value.

2. The vacuum process apparatus according to claim 1,
wherein the control unit compares the differential pressure value and a second set pressure value when the differential pressure value is higher than the first set pressure value, and increases a purge time taken for a purge performed before venting to the atmosphere in the load-lock chamber when the differential pressure value is within a range of the second set pressure value.

3. The vacuum process apparatus according to claim 2,
wherein the purge time to be increased by the control unit is a time period taken for an after-purge performed after a main purge is finished.

4. The vacuum process apparatus according to claim 2,
wherein, when the differential pressure value is higher than the second set pressure value, the control unit compares the differential pressure value and a third set pressure value, and decreases the purge time in the load-lock chamber when the differential pressure value is higher than the third set pressure value.

5. The vacuum process apparatus according to claim 4,
wherein the purge time to be decreased by the control unit is a time period taken for an after-purge performed after a main purge is finished.

6. The vacuum process apparatus according to claim 4,
wherein the second set pressure value to be compared to the differential pressure value by the control unit is a pressure value in a range higher than the first set pressure value and lower than the third set pressure value.

7. The vacuum process apparatus according to claim 1,
wherein the control unit stops the vacuum process of a semiconductor wafer to be performed next when the differential pressure value is lower than the first set pressure value.

8. The vacuum process apparatus according to claim 2,
wherein the control unit outputs an overtime alarm when a sum of the increased purge times exceeds a set time that is previously set.

9. The vacuum process apparatus according to claim 2,
wherein the control unit stops the vacuum process of a semiconductor wafer to be performed next when a sum of the increased purge times exceeds a set time that is previously set.

10. A method of manufacturing a semiconductor device using a vacuum process apparatus including a control unit for controlling a venting process for putting a load-lock chamber in a vacuum state to an atmospheric state in which the load-lock chamber is opened to atmosphere,
the method comprising the steps of:
measuring, by the control unit, a first pressure value that is a pressure inside the load-lock chamber right before venting to the atmosphere and a second pressure value that is a pressure inside the load-lock chamber being vented to the atmosphere;
comparing, by the control unit, a first set pressure value and a differential pressure value that is obtained by subtracting the second pressure value from the first pressure value, and determining, by the control unit, whether or not the differential pressure value is lower than the first set pressure value; and
outputting, by the control unit, an alarm when the control unit determines that the differential pressure value is lower than the first set pressure value.

11. The method of manufacturing a semiconductor device according to claim 10,
the method comprising the step of
comparing, by the control unit, the differential pressure value and a second set pressure value when the differential pressure value is higher than the first set pressure value, and increasing, by the control unit, a purge time taken for a purge performed in the load-lock chamber before venting to the atmosphere when the differential pressure value is within a range of the second set pressure value.

12. The method of manufacturing a semiconductor device according to claim 11,
the method comprising the step of
comparing, by the control unit, the differential pressure value and a third set pressure value when the differential pressure value is higher than the second set pressure value, and decreasing, by the control unit, the purge time in the load-lock chamber when the differential pressure value is higher than the third set pressure value.

13. The method of manufacturing a semiconductor device according to claim 12,
wherein the second set pressure value to be compared to the differential pressure value is a pressure value in a range higher than the first set pressure value and lower than the third set pressure value.

14. The method of manufacturing a semiconductor device according to claim 10,
the method comprising the step of
stopping, by the control unit, a vacuum process of a semiconductor wafer to be performed next when the differential pressure value is lower than the first set pressure value.

15. The method of manufacturing a semiconductor device according to claim 11,
the method comprising the step of
outputting, by the control unit, an overtime alarm when a sum of the increased purge times exceeds a set time that is previously set or stopping, by the control unit, a vacuum process of a semiconductor wafer to be performed next when a sum of the increased purge times exceeds a set time that is previously set.
